(19) United States
(12) Patent Application Publication
(10) Pub. No.: US 2013/0153390 A1
(43) Pub. Date: Jun. 20, 2013

(54) TOUCH SENSOR AND METHOD FOR MANUFACTURING THE SAME

(71) Applicants: Kyu Sang LEE, Gyunggi-do (KR); Sang Su HONG, Gyunggi-do (KR)

(72) Inventors: Kyu Sang LEE, Gyunggi-do (KR); Sang Su HONG, Gyunggi-do (KR)

(73) Assignee: SAMSUNG ELECTRO-MECHANICS CO., LTD., Gyunggi-do (KR)

(21) Appl. No.: 13/427,824

(22) Filed: Mar. 22, 2012

(30) Foreign Application Priority Data
Dec. 19, 2011 (KR) 10-2011-0137354

(51) Int. Cl. H05K 1/00; H01H 11/00

(52) U.S. Cl. 200/600; 29/622

(57) ABSTRACT

Disclosed herein are a touch sensor and a method for manufacturing the same. The touch sensor includes a window substrate, an electrode unit integrally formed on one side surface of the window substrate, an inorganic insulating layer coating the electrode unit, and a chemically strengthened layer formed on the other side surfaces of the window substrate except for the one side surface of the window substrate.

### CROSS REFERENCE TO RELATED APPLICATION

This application claims the benefit of Korean Patent Application No. 10-2011-0137354, filed on Dec. 19, 2011, entitled “Touch Sensor and The Manufacturing Method”, which is hereby incorporated by reference in its entirety into this application.

### BACKGROUND OF THE INVENTION

1. Technical Field

The present invention relates to a touch sensor and a method for manufacturing the same.

2. Description of the Related Art

In recent years, a touch screen panel including a smart phone or a tablet PC has rapidly changed from a resistance film type in the prior art to a capacity type. A GFF scheme which is popularly applied to a capacitive touch sensor, two PET films in which an ITO is deposited/patterned below a window glass are provided.

Currently, as a touch sensor, a glass sensor in a GFF scheme and a GG scheme including an ITO film has been widely used.

Here, when a substrate of the touch sensor is formed of glass, chemical strengthening is needed to prevent damage to the glass. However, when chemically strengthened, and then cut into many pieces, the glass may become cracked or damaged at the time of cutting.

In addition, when the glass is cut into many pieces, each of the cut pieces is subjected to chemical strengthening, and then a touch electrode is formed on each of the cut pieces; consequently, a long manufacturing process is required.

### SUMMARY OF THE INVENTION

The present invention has been made in an effort to provide a touch sensor of which an electrode unit may be coated with a material that does not need to be subjected to chemical strengthening to thereby form an insulating layer, and a method for manufacturing the same.

In addition, the present invention has been made in an effort to provide a touch sensor formed with silicon dioxide, which is an inorganic material that does not need to be subjected to chemical strengthening, as an insulating layer, and a method for manufacturing the same.

According to a preferred embodiment of the present invention, there is provided a touch sensor, including: a window substrate; an electrode unit formed on one side surface of the window substrate; and a chemically strengthened layer formed on the other side surfaces of the window substrate except for the one side.

Also, the electrode unit may include an electrode pattern formed on the one side surface of the window substrate, and an insulating layer coating the electrode pattern.

Also, the insulating layer may be made of an inorganic material.

Also, the inorganic material may be made of silicon dioxide or silicon alkoxide.

Also, the chemically strengthened layer may be formed on the one side surface of the window substrate, and an upper surface or a lower surface of the window substrate.

According to another preferred embodiment of the present invention, there is provided a method for manufacturing a touch sensor, including: forming a plurality of electrode units on one side surface of a window substrate; cutting the window substrate and the plurality of electrode units so that the plurality of electrode units are respectively separated; and forming a chemically strengthened layer by performing chemical strengthening on the other side surfaces of the window substrate except for the one side surface through a chemically strengthening agent.

Also, the forming of the plurality of electrode units may include patterning an electrode and forming an electrode pattern, and coating the electrode pattern with an inorganic material and forming an insulating layer.

Also, the inorganic material may be made of silicon dioxide or silicon alkoxide.

Also, the chemically strengthening agent may be made of potassium nitrate.

Also, the chemically strengthened layer may be formed on the one side surface of the window substrate, and an upper surface or a lower surface of the window substrate.

### BRIEF DESCRIPTION OF THE DRAWINGS

FIG. 1 is an exploded perspective view showing a touch sensor according to an embodiment of the present invention;

FIG. 2 is a side cross-sectional view showing a touch sensor according to an embodiment of the present invention;

FIG. 3 is a flowchart showing a method for manufacturing a touch sensor according to another embodiment of the present invention; and

FIGS. 4A to 8 are cross-sectional views sequentially showing a method for manufacturing a touch sensor according to another embodiment of the present invention.

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, in describing the present invention, a detailed description of related known functions or configurations will be omitted so as not to obscure the subject of the present invention.

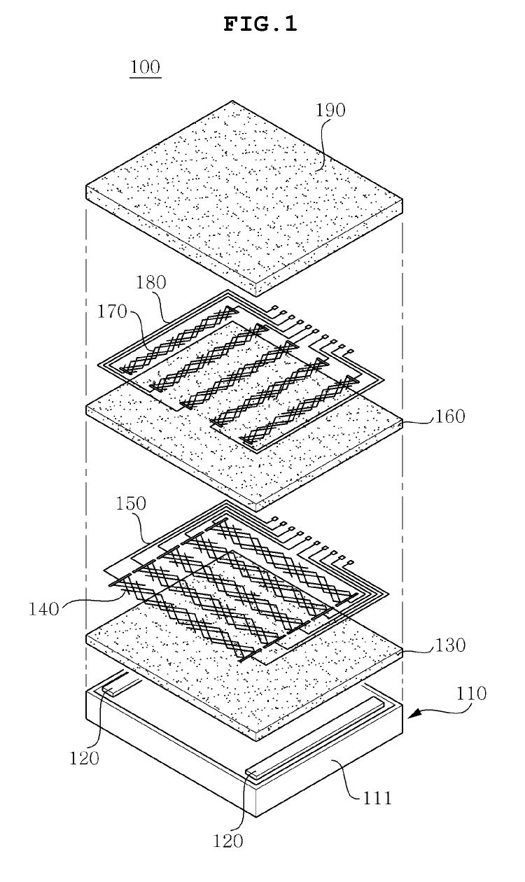

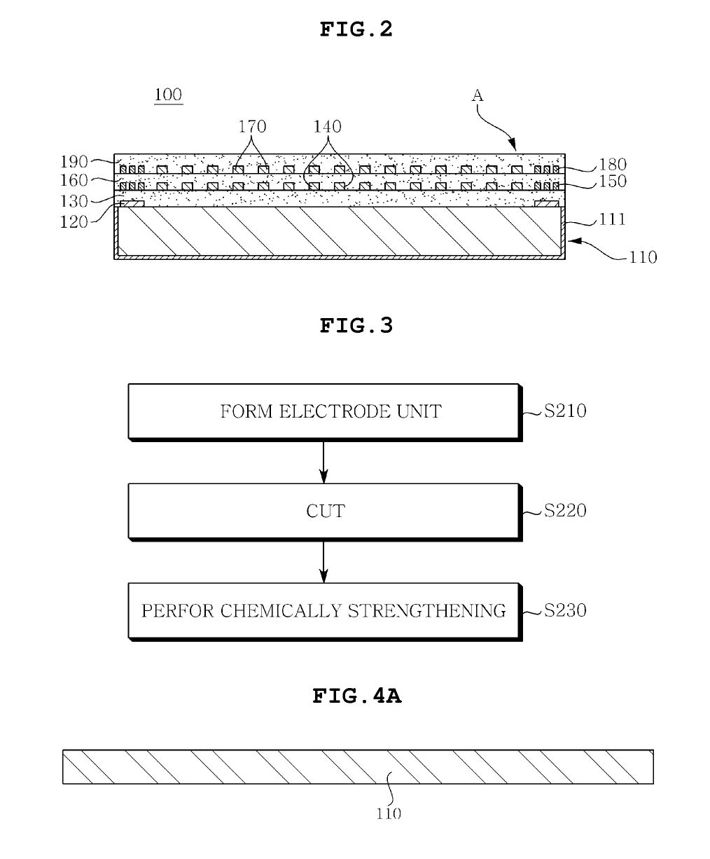

FIG. 1 is an exploded perspective view showing a touch sensor according to an embodiment of the present invention, and FIG. 2 is a side cross-sectional view showing a touch sensor according to an embodiment of the present invention.

Referring to FIGS. 1 and 2, a touch sensor 100 according to an embodiment of the present invention includes a window substrate 110, an electrode unit A that is integrally formed on one side surface of the window substrate 110, and a chemically strengthened layer 111 that is formed on the other side surfaces of the window substrate 110 except for the one side surface of the window substrate 110.

Hereinafter, the touch sensor 100 according to an embodiment of the present invention will be described in detail with reference to FIGS. 1 and 2.

Referring to FIGS. 1 and 2, the window substrate 110 provides a substrate unit that is made of glass or tempered glass, and includes an electrode formed thereon. In this instance, the window substrate 110 may be formed in a rectangular plate shape having a predetermined thickness; however, a shape of the window substrate 110 according to an embodiment of the present invention is not limited thereto.

Referring to FIGS. 1 and 2, the electrode unit A is formed on a surface of the window substrate 110. In this instance, in FIG. 1, the surface of the window substrate 110 signifies an upper surface of the window substrate 110. However, the surface of the window substrate 110 is not limited to the upper surface of the window substrate 110, and may be a lower surface of the window substrate 110.

In addition, the electrode unit A includes an electrode pattern that is formed on a surface of the window substrate 110, and an insulating layer that coats the electrode pattern. Here, the electrode pattern includes a first electrode pattern 140 and a second electrode pattern 170, and the insulating layer includes a second insulating layer 160 and a third insulating layer 190. In addition, the electrode unit A further includes a shielding film 120 that covers an electrode wiring. In this instance, the insulating layer may further include a first insulating layer 130 that coats the shielding film 120.

More specifically, the electrode unit A includes the shielding film 120 that is formed on the surface of the window substrate 110 to cover the electrode wiring, the first insulating layer 130 coats the shielding film 120 to form a protection layer, the first electrode pattern 140 is formed on a surface of the first insulating layer 130, the second insulating layer 160 coats the first electrode pattern to form a protection layer, the second electrode pattern 170 is formed on a surface of the second insulating layer 160, and the third insulating layer 190 coats the second electrode pattern to form a protection layer.

Here, the electrode wiring includes a first electrode wiring 150 and a second electrode wiring 180. In this instance, the first electrode wiring 150 that receives electrical signals from the first electrode pattern 140 is formed at an edge of the first electrode pattern 140, and the second electrode wiring 180 that receives electrical signals from the second electrode pattern 170 is formed at an edge of the second electrode pattern 170.

Here, when the first and second electrode wirings 150 and 180 are made of a metal such as silver paste, the first and second electrode wirings 150 and 180 may be recognized from the outside, such that the shielding film 120 may be formed to prevent the first and second electrode wirings 150 and 180 from being recognized from the outside. The shielding film 120 is formed in a manner such that ink having a low brightness such as black ink is printed on a surface of the window substrate.

In addition, the first and second insulating layers 130 and 160 may provide a region in which the first and second electrode patterns 140 and 170 are to be formed. In this instance, to activate a surface of each of the first and second insulating layers 130 and 160, a high-frequency processing or a primer processing may be performed.

In this manner, by activating the surface of each of the first and second insulating layers 130 and 160, adhesion between the first and second insulating layers 130 and 160 with the first and second electrode patterns 140 and 170 may be improved.

In addition, the first and second electrode patterns 140 and 170 may be made of any one of a metal mesh, metal oxide, and a conductive polymer.

Here, the metal mesh may be formed of a mesh pattern using copper (Cu), aluminum (Al), gold (Au), silver (Ag), titanium (Ti), palladium (Pd), chrome (Cr), or a combination of theses.

Meanwhile, when the first and second electrode patterns 140 and 170 are made of copper (Cu), an outer surface of each of the first and second electrode patterns 140 and 170 are subjected to a black oxide, so that light is prevented from being reflected.

A line width of each of the first and second electrode patterns 140 and 170 is formed as being 7 μm or less, and a pitch thereof is formed as being 900 μm or less, thereby improving visibility. However, the line width and the pitch of the first and second electrode patterns 140 and 170 according to an embodiment of the present invention are not limited thereto.

Here, the conductive polymer has superior flexibility, and has a simple coating process. In this instance, the conductive polymer includes poly-3,4-ethylenedioxythiophene/polystyrene sulfonate (PEDOT/PSS), Polyaniline, polyacetylenes, or polyphenylenevinylene.

In this instance, the first and second electrode patterns 140 and 170 may be formed in a dry process, a wet process, or a direct patterning process. In this instance, the dry process signifies sputtering, evaporation, and the like, and the wet process signifies dip coating, spin coating, roll coating, spray coating, and the like. In addition, the direct patterning process signifies screen printing, gravure printing, inkjet printing, and the like.

In addition, the metal oxide includes indium-tin oxide.

Meanwhile, other than the above described metals, the first electrode patterns 140 is formed of metal silver that is formed by exposing/developing a silver salt emulsion layer.

Referring to FIGS. 1 and 2, the insulating layer is made of an inorganic material. Here, the inorganic material includes silicon dioxide (SiO₂) or silicon alkoxide; however, the inorganic material according to an embodiment of the present invention is not limited thereto.

Referring to FIGS. 1 and 2, the chemically strengthened layer 111 is formed on the other remaining surfaces of the window substrate 110 except for the one side surface of the window substrate 110 in which the electrode unit A is formed. Here, the other surfaces of the window substrate 110 may be a side surface or a lower surface of the window substrate 110 as shown in FIG. 1. However, the other side surfaces of the window substrate 110 according to an embodiment of the present invention are not limited thereto, and may be a side surface and an upper surface of the window substrate 110.

In addition, the chemically strengthened layer 111 is a protection layer of the window substrate 110 that is formed by coating, on a chemically strengthening region of the window substrate 110, a salt paste that is a chemically strengthening agent. In this instance, the salt paste includes, as a mixed medium, salts such as potassium nitrate (KNO₃), potassium chloride (KCl), or the like, and ethanol oil that has excellent adsorbability against a glass surface while easily dissolving the salts.

The chemically strengthening agent may be coated in a silk screen method or a roller coating method.

FIG. 3 is a flowchart showing a method for manufacturing a touch sensor according to another embodiment of the present invention, and FIGS. 4A to 8 are cross-sectional views sequentially showing a method for manufacturing a touch sensor according to another embodiment of the present invention.

Referring to FIG. 3, a method for manufacturing a touch sensor according to another embodiment of the present invention includes forming an electrode unit, forming an insulating layer, cutting, and performing chemical strengthening.

Hereinafter, the method for manufacturing the touch sensor according to another embodiment of the present invention will be described in detail with reference to FIGS. 3 to 8. In addition, the method for manufacturing the touch sensor according to another embodiment of the present invention relates to a method for manufacturing the touch sensor according to an embodiment of the present invention, and the same reference numerals denote the same configuration.

### Another Embodiment

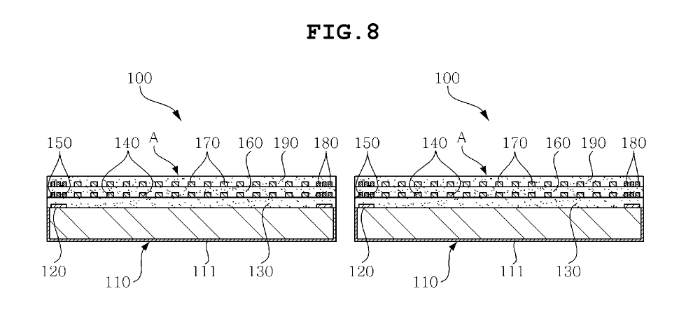

Referring to FIGS. 3 and 8, in forming an electrode unit S210, an electrode unit A is integrally formed on a surface of the window substrate 110. In this instance, the electrode unit A may be composed of a plurality of columns and a plurality of rows on the surface of the window substrate 110.

First, referring to FIGS. 4C to 5B, and FIG. 8, the first electrode pattern 140 is formed on the surface of the window substrate 110 to form the electrode unit A, and the first electrode pattern is coated to form the second insulating layer 160. In this instance, the first insulating layer 130 is formed between the window substrate 110 and the first electrode pattern 140, so that the first electrode pattern 140 is formed on a surface of the first insulating layer 130.

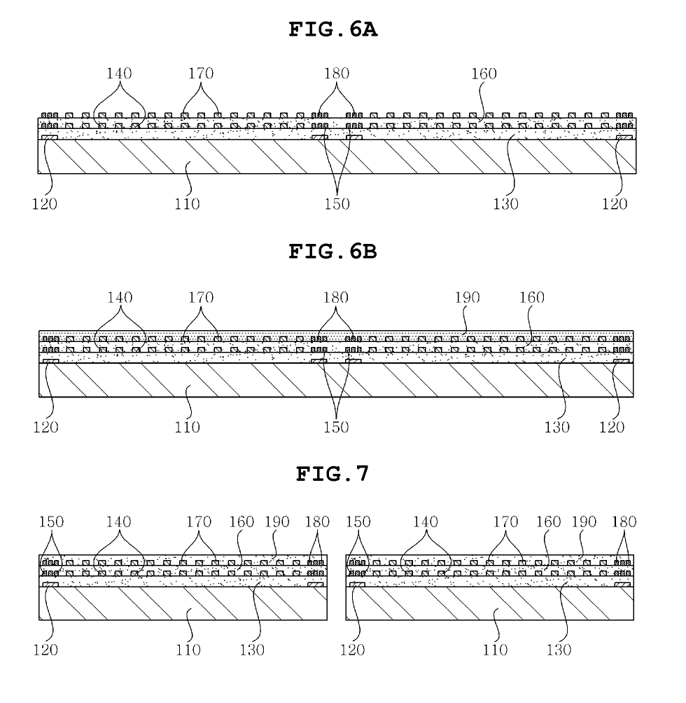

Referring to FIGS. 6A to 6B, the second electrode pattern 170 is formed on a surface of the second insulating layer 160, and the second electrode pattern is coated to form the third insulating layer 190.

In addition, referring to FIGS. 2, 5A, and 6B, the first electrode wiring 150 that receives electrical signals from the first electrode pattern 140 is formed at an edge of the first electrode pattern 140, and the second electrode wiring 180 that receives electrical signals from the second electrode pattern 170 is formed at an edge of the second electrode pattern 170.

In addition, referring to FIGS. 4A and 4C, the method for manufacturing the touch sensor further includes forming the first insulating layer 130. Here, the first insulating layer 130 is formed in a manner such that the shielding film 120 that covers the first and second electrode wirings 150 and 180 is formed on a surface of the window substrate 110, and the shielding film 120 is then coated. In this instance, the first electrode pattern 140 may be formed on a surface of the first insulating layer 130.

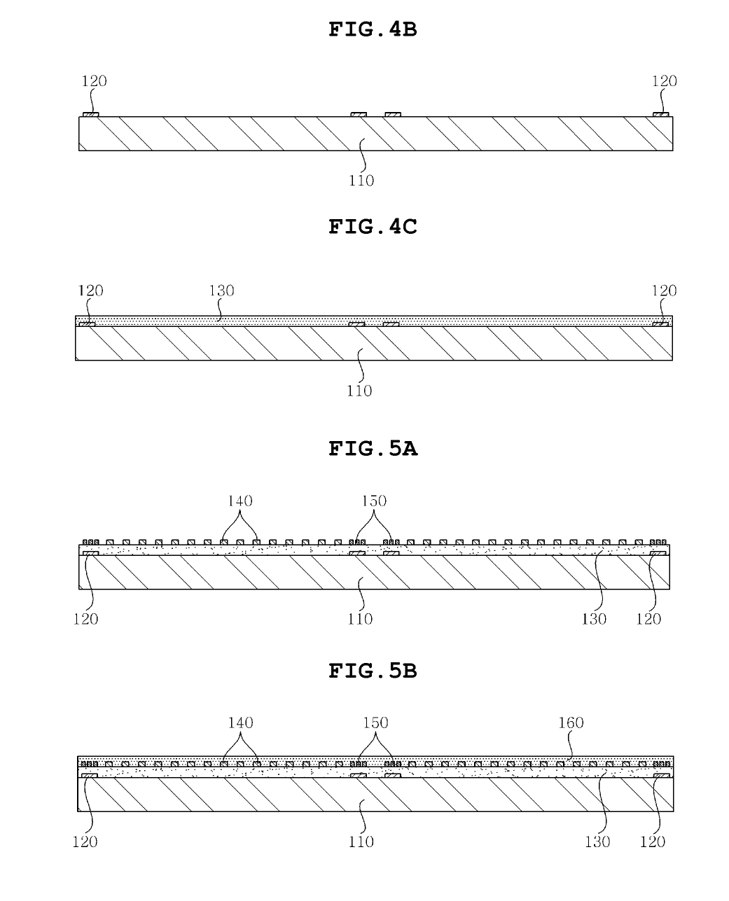

Here, referring to FIG. 5A, the first insulating layer 130 coats and protects the shielding film 120, and provides a substrate unit in which the first electrode pattern 140 and the first electrode wiring 150 are formed.

In addition, referring to FIG. 6A, the second insulating layer 160 coats and protects the first electrode pattern 140 and the first electrode wiring 150, and provides a substrate unit in which the second electrode pattern and the second electrode wiring 180 are formed.

In addition, referring to FIG. 6B, the third insulating layer 190 coats and protects the second electrode pattern and the second electrode wiring 180.

In addition, when the first and second electrode wirings 150 and 180 include a metal such as silver paste, the first and second electrode wirings 150 and 180 are recognized from the outside, so that the shielding film 120 may be formed to prevent the first and second electrode wirings 150 and 180 from being recognized from the outside. The shielding film 120 is formed in a manner such that ink having a low brightness such as black ink is printed on a surface of the window substrate.

In addition, the first and second insulating layers 130 and 160 may provide a region in which the first and second electrode patterns 140 and 170 are to be formed. In this instance, to activate a surface of each of the first and second insulating layers 130 and 160, a high-frequency processing or a primer processing may be performed.

In this manner, by activating the surface of each of the first and second insulating layers 130 and 160, adhesion between the first and second insulating layers 130 and 160 with the first and second electrode patterns 140 and 170 may be improved.

In addition, the first and second electrode patterns 140 and 170 may be made of any one of a metal mesh, metal oxide, and a conductive polymer.

Here, the metal mesh may be formed of a mesh pattern using copper (Cu), aluminum (Al), gold (Au), silver (Ag), titanium (Ti), palladium (Pd), chrome (Cr), or a combination of theses.

Meanwhile, when the first and second electrode patterns 140 and 170 are made of copper (Cu), an outer surface of each of the first and second electrode patterns 140 and 170 are subjected to a black oxide, so that light is prevented from being reflected.

A line width of each of the first and second electrode patterns 140 and 170 is formed to be 7 μm or less, and a pitch thereof is formed as to be 900 μm or less, thereby improving visibility. However, the line width and the pitch of the first and second electrode patterns 140 and 170 according to a another embodiment of the present invention are not limited thereto.

Here, the conductive polymer has superior flexibility, and a simple coating process. In this instance, the conductive polymer includes poly-3,4-ethylenedioxythiophene/polystyrene sulfonate (PEDOT/PSS), Polyaniline, polyacetylenes, or polyphenylenevinylene.

In this instance, the first and second electrode patterns 140 and 170 may be formed in a dry process, a wet process, or a direct patterning process. Furthermore, the dry process signifies sputtering, evaporation, and the like, and the wet process signifies dip coating, spin coating, roll coating, spray coating, and the like. In addition, the direct patterning process signifies screen printing, gravure printing, inkjet printing, and the like.

In addition, the metal oxide includes indium-tin oxide.

In addition, other than the above described metals, the first electrode pattern 140 to is formed of metal silver that is formed by exposing/developing a silver salt emulsion layer.

In addition, the window substrate 110 is made of glass or tempered glass. In addition, the surface of the window substrate 110 may be an upper surface or a lower surface of the window substrate 110.

Meanwhile, the first insulating layer 130, the second insulating layer 160, and the third insulating layer 190 are made of an inorganic material. Here, the first insulating layer 130, the second insulating layer 160, and the third insulating layer 190 may be made of silicon dioxide (SiO₂) that is formed by printing silicon (Si) by sputtering and heating the printed silicon up to 500° C. to 700° C. However, the inorganic material of the insulating layer according to another of the present invention is not particularly limited to silicon dioxide (SiO₂), and the insulating layer may be made of, for example, silicon alkoxide.

Therefore, the electrode unit A of each of the first, the second, and the third insulating layers 130, 160, and 190 which are formed during the manufacturing method for the touch sensor according to another of the present invention is protected, so that the electrode unit A does not need to be subjected to chemical strengthening.

Referring to FIG. 7, in cutting 5220, a plurality of electrode units A is cut to be respectively separated in the window substrate 110. In this instance, the electrode unit A is composed of a plurality of columns and a plurality of rows, and the plurality of columns and the plurality of rows cut between the plurality of electrode units A while cutting the window substrate 110, thereby forming a plurality of touch sensors 100.

Referring to FIG. 8, in performing chemical strengthening 5230, chemical strengthening is performed on the other surface of the window substrate 110 in the plurality of touch sensors 100 that has been respectively cut during the cutting. In this instance, the chemically strengthened layer 111 is formed on the other remaining surfaces of the window substrate 110 except for the surface of the window substrate 110 in which the electrode unit A is formed, through a chemically strengthening agent.

Here, the other surfaces of the window substrate 110 may be one side surface of a lower surface of the window substrate 110 as shown in FIG. 1. However, the other surfaces of the window substrate 110 according to another of the present invention are not limited thereto, and may be one side surface or an upper surface of the window substrate 110.

In addition, the chemically strengthening agent includes salts such as potassium nitrate (KNO₃), potassium chloride (KCl), or the like, and ethanol oil that has excellent adsorbability against a glass surface while easily dissolving the salts.

In addition, the chemically strengthening agent may be coated in a silk screen method or a roller coating method.

Accordingly, the chemically strengthening agent is coated on the other surfaces of the window substrate 110, so that the chemically strengthening layer 111 that is a protection layer of the window substrate 110 may be formed.

In this instance, the chemically strengthening layer 111 may be more easily formed by heating at 400° C. to 500° C. for 4 to 6 hours.

The chemically strengthening layer 111 formed in the above method forms a protection layer that protects the window substrate 110 in significantly thermally, chemically, and physically stable states.

Accordingly, the window substrate 110 is protected by the chemically strengthening layer 111 formed in the method for manufacturing the touch sensor according to another of the present invention, so that a separate strengthening process does not need to be performed.

In addition, in the method for manufacturing the touch sensor according to another of the present invention, the window substrate 110 that forms a plurality of electrode units A is cut into many pieces, and then the cut many pieces are subjected to chemical strengthening, so that damage of the window substrate 110 occurring in the cutting process after performing the chemical strengthening may be prevented.

In addition, in the method for manufacturing the touch sensor according to another of the present invention, the window substrate 110 is cut into many pieces, and then the electrode unit A is respectively formed in the plurality of cut window substrates 110, thereby reducing a long manufacturing time.

According to s of the present invention, the touch sensor may be coated with a material which does not need to be subjected to chemical strengthening, thereby enabling mass production of the touch substrate.

In addition, according to s of the present invention, as the insulating layer, silicon dioxide as the inorganic material that does not need to be subjected to chemical strengthening is adopted, thereby exhibiting superior heat resistance and chemical resistance, and being resistant to external shocks.

Although the preferred s of the present invention have been disclosed for illustrative purposes, they are for specifically explaining the present invention and thus a touch sensor and a method for manufacturing the same according to the present invention are not limited thereto, but those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. A touch sensor, comprising:
a window substrate;
an electrode unit formed on one side surface of the window substrate; and
a chemically strengthened layer formed on the other side surfaces of the window substrate except for the one side surface.

2. The touch sensor as set forth in claim 1, wherein the electrode unit includes an electrode pattern formed on the one side surface of the window substrate, and an insulating layer coating the electrode pattern.

3. The touch sensor as set forth in claim 2, wherein the insulating layer is made of an inorganic material.

4. The touch sensor as set forth in claim 3, wherein the inorganic material is made of silicon dioxide or silicon alkoxide.

5. The touch sensor as set forth in claim 1, wherein the chemically strengthened layer is formed on the one side surface of the window substrate, and an upper surface or a lower surface of the window substrate.

6. A method for manufacturing a touch sensor, comprising:
forming a plurality of electrode units on one side surface of a window substrate;
cutting the window substrate and the plurality of electrode units so that the plurality of electrode units are respectively separated; and
forming a chemically strengthened layer by performing chemical strengthening on the other side surfaces of the window substrate except for the one side surface through a chemically strengthening agent.

7. The method as set forth in claim 6, wherein the forming of the plurality of electrode units includes patterning an electrode and forming an electrode pattern, and coating the electrode pattern with an inorganic material and forming an insulating layer.

8. The method as set forth in claim 7, wherein the inorganic material is made of silicon dioxide or silicon alkoxide.

9. The method as set forth in claim 6, wherein the chemically strengthening agent is made of potassium nitrate.

10. The method as set forth in claim 6, wherein the chemically strengthened layer is formed on the one side surface of the window substrate, and an upper surface or a lower surface of the window substrate.
